(19) United States
(12) Patent Application Publication
(10) Pub. No.: US 2013/0160563 A1
(43) Pub. Date: Jun. 27, 2013

(54) HOUSING PART FOR AN ELECTRICAL SENSOR AS WELL AS A METHOD FOR MANUFACTURING THE HOUSING PART

(71) Applicants: Peter DINGLER, Aalen-Ebnat (DE); Michael ULMER, Eislingen (DE)

(72) Inventors: Peter DINGLER, Aalen-Ebnat (DE); Michael ULMER, Eislingen (DE)

(21) Appl. No.: 13/672,069

(22) Filed: Nov. 8, 2012

(30) Foreign Application Priority Data
Dec. 22, 2011 (DE) 10 2011 089 608.2

(51) Int. Cl. G01D 11/24; H05K 5/02

(52) U.S. Cl. CPC G01D 11/245; H05K 5/0247
USPC 73/855; 29/592.1

(57) ABSTRACT

A housing part for a strain sensor is described. The strain sensor includes at least one sensor element. The housing part includes an interior space for receiving the sensor element. The housing part includes a contract layer of electrically conducting material produced by way of thick film technology, the contact layer being intended for realization of an electrical feedthrough from the interior space to the outside.

### PRIORITY STATEMENT

The present application hereby claims priority under 35 U.S.C. §119 to German patent application number DE 10 2011 089 608.2 filed Dec. 22, 2011, the entire contents of which are hereby incorporated herein by reference.

### FIELD

At least one embodiment of the invention generally relates to a housing part for an electric sensor, in particular a strain sensor. At least one embodiment of the invention also generally relates to a method of manufacturing this housing part, as well as a sensor produced using the housing part.

### BACKGROUND

EP 2 056 085 A1 describes a housing for a strain sensor having a base part, a central part, and a lid part. A sensor element is glued to the base part, wherein the sensor element contains a surface wave component. The latter is a so-called SAW resonator (SAW=surface acoustic wave) in EP 2 056 085 A1. The central part is designed as tubular in shape and accommodates the sensor element in its interior space in assembled state. The central part is provided with an opening through which the two electric wires for connecting the sensor element are guided. The opening is gas-tight sealed with fused glass before the base part and the central part are assembled. The base part, the central part, and the lid part are made, for example, from stainless steel and are gas-tight glued or welded to each other.

### SUMMARY

At least one embodiment of the invention is directed to creating a housing part that can be more easily produced.

At least one embodiment of the invention is directed to a housing part and at least one embodiment of the invention is directed to a method for manufacturing a housing part. At least one embodiment of the invention is directed to a sensor and at least one embodiment is directed to its production.

According to at least one embodiment of the invention, the housing part has a contact layer of electrically conductive material made using thick film technology, wherein the contact layer is provided for realizing an electric feedthrough out of an interior space for accommodating a sensor element to the outside.

Additional features, applications, and advantages of the invention can be drawn from the following description of the example embodiments of the invention shown in the figures. All of the described or depicted features, separately or in any combination, constitute the object of the invention, regardless of if they are summarized in the patent claims or their retroactive application, as well as independently from their formulation or representation description and the figures.

### BRIEF DESCRIPTION OF THE DRAWINGS

FIG. 1 shows a schematic perspective view of an example embodiment of a first module of a strain sensor according to the invention;

FIG. 2a shows a schematic perspective view of an example embodiment of a second module of a strain sensor according to the invention;

FIG. 2b shows a schematic exploded view of the second module of FIG. 2;

FIG. 3a shows a schematic perspective view of the strain sensor according to an embodiment of the invention after assembling the first and the second module;

FIG. 3b shows a schematic plan view of the assembly of FIG. 3a; and

FIG. 4 shows a schematic perspective view of the strain sensor according to an embodiment of the invention.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. The use of similar or identical reference numbers in the various drawings is intended to indicate the presence of a similar or identical element or feature.

### DETAILED DESCRIPTION OF THE EXAMPLE EMBODIMENTS

The present invention will be further described in detail in conjunction with the accompanying drawings and embodiments. It should be understood that the particular embodiments described herein are only used to illustrate the present invention but not to limit the present invention.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

Specific structural and functional details disclosed herein are merely representative for purposes of describing example embodiments of the present invention. This invention may, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

According to at least one embodiment of the invention, the housing part has a contact layer of electrically conductive material made using thick film technology, wherein the contact layer is provided for realizing an electric feedthrough out of an interior space for accommodating a sensor element to the outside.

The production of the contact layer comprising the electric feedthrough by way of thick film technology is significantly easier to implement than the glass seal of the opening used, for example, for leading through the wires in the state of the art. The electric feedthrough realized using thick film technology can furthermore be configured much smaller with regard to its dimensions than the opening fused with glass in the state of the art. In comparison with the known glass feedthroughs, there is also a significantly lower risk that the material will crack with greater elongation, with the electric feedthrough produced using thick film technology, which is of particular importance if a strain sensor is used. An additional advantage of the electric feedthrough is that it can be easily and flexibly adapted to different applications and application functions. With the electric feedthrough made using thick film technology, it is moreover possible to easily produce an overall leak-proof sensor housing. Another significant advantage of the use of thick film technology is that it allows for so-called panel production in the manufacture of the sensor according to the invention. This means that a plurality of housing parts can be simultaneously produced. This is not possible in contrast in the case of the known glass feedthroughs.

In another embodiment of the invention are provided a first and a second insulating layer made of electrically insulating material, which are produced by way of thick film technology and between which the contact layer is arranged. An insulation of the electric feedthrough is easily accomplished in this way.

It is particularly advantageous herein if the first insulating layer has an area that protrudes over the second insulation layer, so that the contact layer can extend in this case from the interior space into the overlying area. In this way, the electric feedthrough from the interior space to the outside is realized in a simple way in the overlaying area.

It is furthermore possible to configure each of the two insulating areas with many layers. It is accordingly also possible to configure the subsequent contact and insulating layers with many layers and in this way realize a plurality of conductive layers.

The use of thick layer technology also allows the production of the contact layer, at least in part, from a material that has a higher electric resistance. Resistances can be integrated in this way directly into the contact layer. It is accordingly possible, particularly if high-frequency signals are used, to assemble other electric components, and thus entire electric circuits, by way of thick film technology as well as to optionally integrate these, at least in part, into the contract layer.

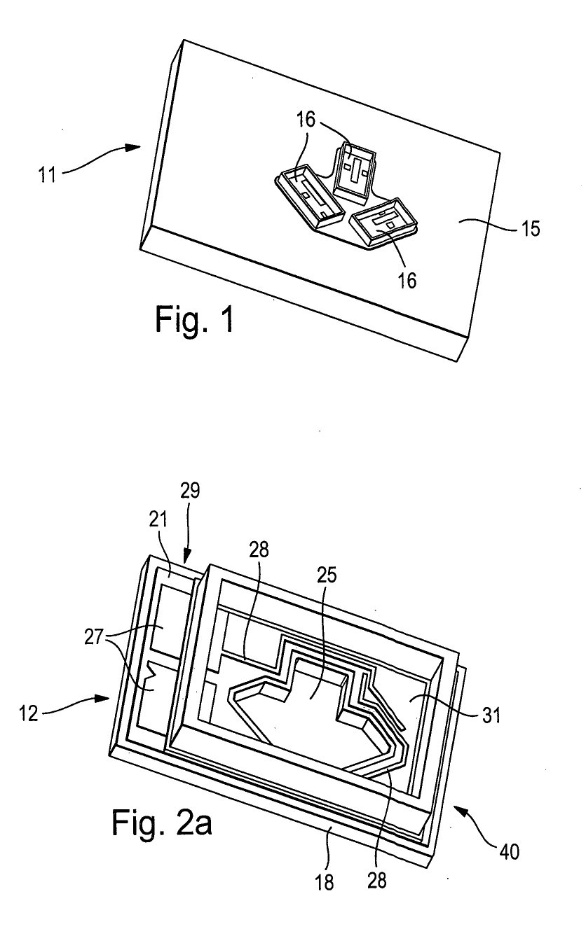

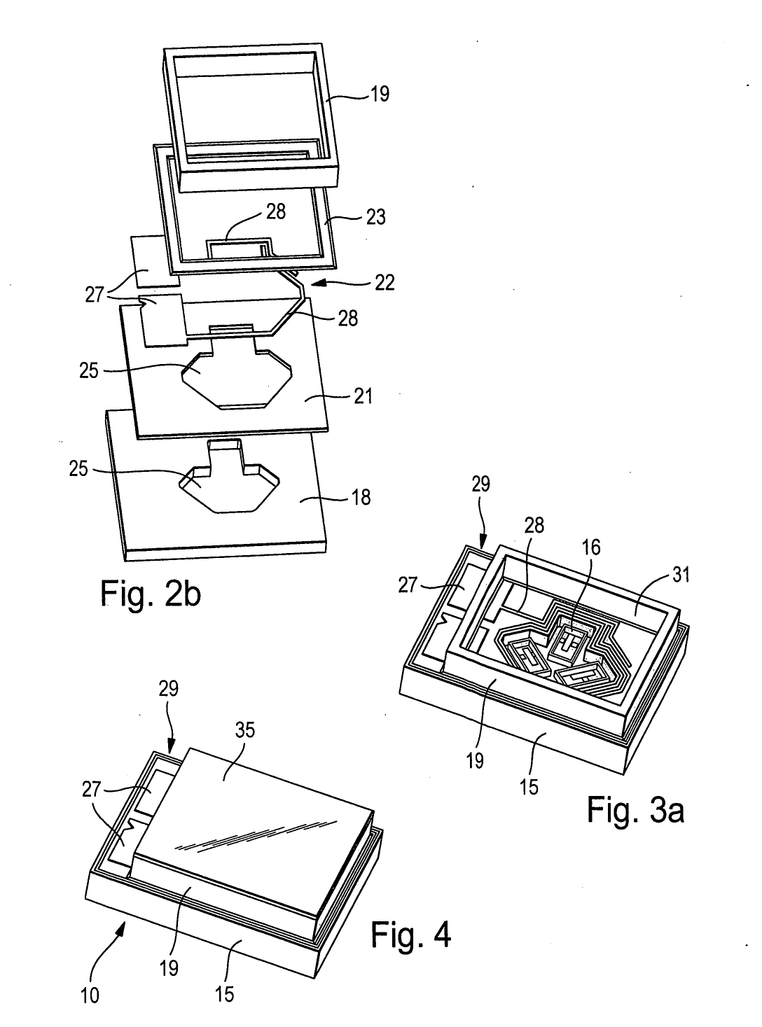

FIG. 1 shows a first module 11 of a strain sensor 10 and FIGS. 2a, 2b show a second module 12 of the strain sensor 10. The strain sensor 10 is shown in FIG. 4.

The first module 11 has a base plate 15 and three sensor elements 16.

The base plate 15 has a flat shape and is preferably made of a metal. In this example embodiment, the base plate 15 has a rectangular shape. It is understood that the base plate 15 can also be provided with another shape. The thickness of the baseplate 15 is preferably less than 2 mm.

The three sensor elements 16 are attached in a median, central region of the baseplate 15. At least two of the three sensor elements 16 preferably have an identical construction and each have one preferred axis. The two sensor elements 16 are at an angle with respect to each other with regard to the preferred axis.

At least two of the three sensor elements 16 are capable of detecting a strain in the direction of their preferred axis. Each of these two sensor elements 16 is provided with a surface wave component for this purpose. The latter can be, for example, a SAW resonator or a SAW delay line 8 (SAW=surface acoustic wave). The surface wave component can preferably be realized by way of corresponding electrode structures on a piezoelectric crystal.

During the production of the first module 11, the three sensor elements 16 are arranged on the baseplate 15, then adjusted, and glued in this state, for example, to the baseplate 15. It is understood that the attachment of the three sensor elements 16 to the baseplate 15 can also be configured in other ways.

The second module 12 has a lower frame 18, a thick film structure, and an upper frame 19. The thick film structure is intended for realization of an electric feedthrough. The thick film structure is provided for this purpose with an electrically conductive layer that extends between an interior space described below and an overlying area also described below. The electric feedthrough is provided so that electric signals, particularly high-frequency signals, can be transmitted via said feedthrough.

The thick film structure has a lower insulating layer 21, a contact layer 22, and an upper insulating layer 23. According to FIG. 2b, the structure of the frames and layers from bottom to top is as follows: lower frame 18, lower insulating layer 21, contact layer 22, upper insulating layer 23, upper frame 19.

The lower frame 18 is made of metal and has a rectangular and flat shape. The rectangular shape of the lower frame 18 is adapted to the rectangular shape of the baseplate 15. It is understood that the lower frame can also have a different shape. The thickness of the lower frame 18 is preferably less than 2 mm.

An opening 25, which is somewhat larger than the surface approximately taken up by the three sensor elements 16 on the baseplate 15, is located in a median, central region in the lower frame 18, so that the three sensor elements 16 can be inserted into or guided through the opening 25 during assembly of the first and second module 11, 12.

The lower insulating layer 21 has the rectangular shape of the lower frame 18 and has a corresponding opening 25 for the sensor elements 15. It is understood that the lower insulating layer 21 can also have a different shape. The lower insulating layer 21 is made from an electrically insulating material and is preferably applied over the entire surface of the lower frame 18 by means of a screen printing process. The lower insulating surface 21 can have one or several layers.

The contact layer 22 is made from an electrically conductive material. The electric conduction to the three sensor elements 15 is realized with the aid of the contact layer 22. In this embodiment, the contact layer 22 has two approximately rectangular connecting surfaces 27, to each of which a conductor 28 is connected. As can be seen particularly in FIG. 2a, the two conductors 28 run in the direction toward the opening 25, and in part around the opening 25.

The two conductors 28 and the two connecting surfaces 27 form a two-conductor structure, via which electric signals can be transmitted. It is understood that different kinds of conductor structures could also be used, for example, a microstrip line and/or a repeater line and/or an grounded coplanar line, and/or a coplanar repeater line or the like. The used conductor structure is preferably particularly well suited for the transmission of high frequency signals.

The contact layer 22 between the two conductive paths 28 can additionally be made at least in part from a material with a relatively high electrical resistance. A parallel resistance, which can serve as overvoltage protection (ESD=electrostatic discharge), can especially be formed in this way using thick film technology.

The contact layer 22 is preferably applied by means of a screen printing method to the surface of the lower insulating layer 21. There is actually no electrical connection between the contact layer 22 and the lower frame 18 because of the lower insulating layer 21. However, it can be provided that at least one of the two connecting surfaces 27 is electrically connected to the frame 18.

The upper insulating layer 23 has a frame-shaped configuration, wherein the dimensions of the frame in the transversal direction correspond approximately to the dimensions of the rectangular shape of the lower frame 18. As will be explained in more detail, the rectangular shape of the lower frame 18 and the lower insulating layer 21 projects in longitudinal direction beyond the rectangular shape of the upper insulating layer 23 and creates an overlaying area 29. The width of the frame of the upper insulating layer 23 is dimensioned in such a way that the upper insulating layer 23 does not cover the opening 25 and the conductors 28. It is understood that the upper insulating layer 23 can also have a different shape.

The upper insulating layer 23 is made from an electrically insulating material and is preferably applied by means of a screen printing method on the surface of the lower insulating layer 21. The upper insulating layer 23 can be configured with one or several layers.

The upper frame 19 has the frame shape of the upper insulating layer 23. On the other hand, the width of the frame is dimensioned in such a way that the upper frame 19 does not cover the opening 25 and the conductive paths 28. Reference is made to FIG. 2a, as an example, where the opening 25 and the conductive paths 28 can be discerned inside the frame-shaped upper frame 19. It is understood that the upper frame 19 can also have a different shape. The height of the upper frame 19 is preferably less than 2 mm.

The upper frame 19 is made from a metal and can be soldered or glued onto the upper insulating layer 23. There is no electrical connection between the contact layer 22 and the upper frame 19 because of the upper insulating layer 23.

As can be especially seen in FIG. 2a and as was previously mentioned, the lower frame 19 and the lower insulating layer 21 are designed somewhat longer in longitudinal direction than the contact layer 22, the upper insulating layer 23, and the upper frame 19. The two connecting surfaces 27 of the contact layer 22 extend into this overlaying area 29. The two connecting surfaces 27 extend preferably from one side to the other side of the frame of the upper insulating layer 23 or the upper frame 19.

If the area formed by the frame of the upper insulating layer 23 and the upper frame 19 is identified as an interior space 31, the conductive paths 28 are then arranged inside this interior space 31, while the connecting surfaces 27 are situated at least in part outside the interior space 31 in the overlaying area.

An electrical feedthrough extends thus from the interior space 31 to the outside within the thick film structure. The electrical feedthrough is preferably realized by means of the contact layer 22, which, in this exemplary embodiment is comprised particularly of the conductors 28. The contact layer 22 is arranged herein between the two insulating layers 21, 23, wherein the lower insulating layer 21 has the overlaying area 29 and the contact layer 22 extends into this overlaying area 29.

The production of the second module 12 can be carried out independently from the manufacture of the first module 11.

The lower frame 18 is aligned and held in a mounting device in order to manufacture the second module 12. The lower insulating layer 21, the contact layer 22, and the upper insulating layer 23 are then assembled on the lower frame 18 using thick film technology. The alignment of the lower insulating layer 21, the contract layer 22, and the upper insulating layer 23 is therefore determined by the alignment of the lower frame 18 in the mounting device. If necessary, additional markings or similar can be used for the purpose of alignment. The upper frame 19 is then attached to the upper insulating layer 23. This can be accomplished, if necessary, by means of an assembly utilizing thick film technology. The alignment of the upper frame 19 can be determined, in turn, by the alignment of the lower frame 18 in the mounting device. Further mounting devices can be alternatively or additionally provided for the upper frame 19.

The individual layers of the second module 12 are formed one after the other and fired in each case in a kiln. This can preferably be done at approximately 850 degrees. These kiln processes can be carried out, if necessary, with the aid of an inert gas.

After the production of the second module 12, the structure of this module 12 constitutes a gas-tight component. This means that in particular the transitions between the individual layers and the frame of the second module 12 are gas tight.

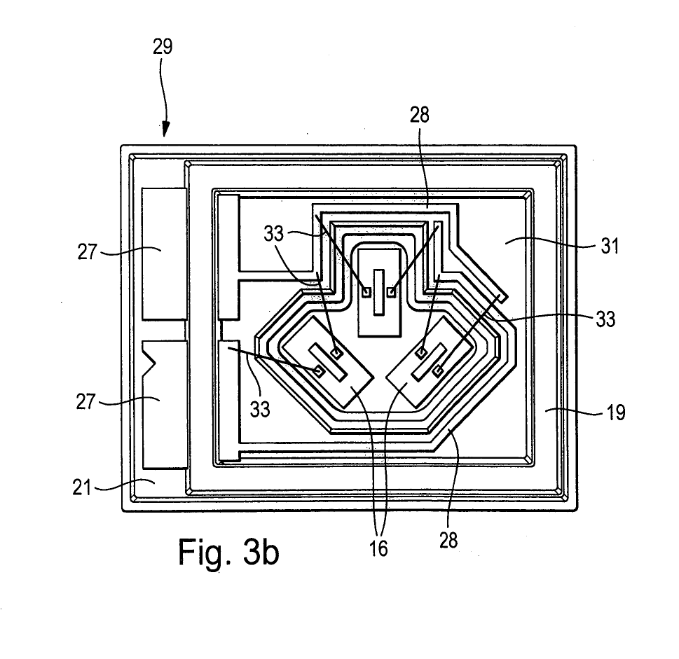

After completion of the first and second modules 11, 12, the two modules are joined. The assembled modules 11, 12 are shown in the FIGS. 3a, 3b.

As can be seen in FIGS. 3a, 3b, and as previously explained, the three sensor elements 16 of the first module 11 project through the opening 25 of the second module 12. The three sensor elements 16 of the first module 11 are thus situated inside the interior space 31 formed by the second module 12.

The baseplate 15 of the first module 11 is welded or soldered or glued to the lower frame 18 of the second module 12. A gas-tight welded seam is preferably drawn between all four longitudinal and transversal sides of the lower frame 18 and the baseplate 15. This can be carried out, for example, using a laser welding process, if necessary with the aid of an inert gas.

The three sensor elements 16, which are now in stationary location inside the interior space, are then electrically connected to the connecting surfaces 27. So-called wedge bonding or ball bonding can be used, for example, for this purpose. The resulting bond wires 33 are schematically drawn in between the three sensor elements 16 and the conductors 28 or the connecting surfaces 27 in FIG. 3a. The contact points of the bond wires 33 on the conductors 28 can be selected herein almost at will.

The interior space 31 is sealed with a lid 35 after the first and the second modules 11, 12 have been joined. The strain sensor 10, which has now been completed in this manner, is shown in FIG. 4.

The lid 35 has a flat shape and is made, for example, of metal. The lid is rectangular in shape and adapted to the rectangular shape of the upper frame. It is understood that the lid 35 can also have a different shape. The thickness of the lid is preferably less than 1 mm.

The lid 35 is welded or soldered or glued to the upper frame 19 of the second module 12. A gas-tight welded seam is preferably drawn between all four longitudinal and transversal sides of the upper frame 19 and the lid 35. This can be carried out, for example, using a laser welding process.

The sealing of the interior space 31 with the lid 35 is preferably carried out in a space that is first evacuated and then filled with gas, for example, with nitrogen-helium. In this way, the interior space 31 of the strain sensor 10 is not filled with air, but rather with gas. The three sensor elements 16, and in particular their respective surface wave components, each of which is realized on a piezoelectric crystal, are also not surrounded by air, but rather by the gas. In this way, the sensor elements 16 are especially protected from chemical corrosion. A leakage test can also be performed if necessary on the strain sensor 10 with the aid of the gas filling.

The alignment of the lid 35 on the upper frame 19 can be achieved with the aid of a corresponding impression on the underside of the lid 35 or by means of other assembly devices.

As previously explained, the production of the first and the second module 11, 12 can be carried out separately and independently, particularly with respect to time and location. The second module 12, as shown particularly in FIG. 2a, constitutes as such a housing part 40 for the strain sensor 10, as shown in FIG. 4. This housing part 40 or the second module 12 constitutes a separate component. The separate housing part 40 must then be combined, as previously explained, with the first module 11 and sealed with the lid 35 in order to form the strain sensor 10 as a whole.

The strain sensor 10 completed in the described way, which is shown in FIG. 4, can be assembled, for example, on a metallic shaft or similar. For example, the strain sensor 10 can be arranged with the aid of two axially running weld seams in particular within a planar recess of the shaft. Signals can be coupled into the two similar sensor elements 16 of the strain sensor via the electric feedthrough. A torque acting on the shaft in the direction of rotation produces an elongation of the baseplate 15 and thus of the two similar sensor elements 16. This elongation of said two sensor elements 16 results in a detuning of the coupled signals. The detuned signals are read out via the electrical feedthrough from the strain sensor 10 and then processed in an evaluator. The torque acting on the shaft can be determined by the evaluator from the detuned signals.

In particular the baseplate 15 and the lower and the upper frame 18, 19 and/or the lid 35 are made from the same material. In this case, the previously mentioned components display essentially the same temperature-dependent properties, in particular the same coefficient of expansion. Temperature-dependent tensions between these components can be prevented or at least reduced in this way.

It is understood that a multilayer assembly of insulating layers and contact layers can also be accomplished using thick film technology. A plurality of conductive planes, which are insulated from each other, can be realized in this way, via which a plurality of electric signals can then be transmitted.

It is also noted that other electrical components, for example, inductances and/or capacitances, can be realized in particular if high frequency signals are utilized with the aid of thick film technology. Matching networks or the like, for example, can be produced for the sensor elements 16 with these components.

Not only the described electrical feedthrough can be realized overall with the aid of thick film technology, but also other conducting structures and/or components can be produced at the same time.

It is understood that the contact layer 22, which is produced using thick film technology and forms an electric feedthrough, can be utilized not only in the strain sensor 10 described in this exemplary embodiment 10, but also generally in any kind of electrical sensor. The described contact layer 22 can also be used, for example, in a corresponding manner for a pressure sensor or a temperature sensor or the like.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combinable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims.

Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

Further, elements and/or features of different example embodiments may be combined with each other and/or substituted for each other within the scope of this disclosure and appended claims.

Still further, any one of the above-described and other example features of the present invention may be embodied in the form of an apparatus, method, system, computer program, tangible computer readable medium and tangible computer program product. For example, of the aforementioned methods may be embodied in the form of a system or device, including, but not limited to, any of the structure for performing the methodology illustrated in the drawings.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A housing part for an electric sensor including at least one sensor element, the housing part including an interior space for receiving the at least one sensor element, the housing part comprising:
a contact layer produced from electrically conducting material utilizing thick film technology, said contact layer being provided to realize an electrical feedthrough from the interior space to outside the housing part.

2. The housing part of claim 1, further comprising:
a first and a second insulating layer, made from electrically insulating material and produced using thick film technology, the contact layer being arranged between the first and a second insulating layer.

3. The housing part of claim 2, wherein the first insulating layer includes an area that projects over the second insulating layer, and wherein the contact layer extends from the interior space into the projecting area.

4. The housing part of claim 1, wherein the contact layer includes at least one of
at least one electric connecting area, and
at least one electric line.

5. The housing part of claim 1, further comprising:
an upper frame, surrounding the interior space.

6. The housing part of claim 5, wherein the upper frame is arranged on one side of the contact layer and includes a frame shape.

7. The housing part of claim 6, further comprising:
a lower frame, arranged on the other side of the contact layer.

8. The housing part of claim 7, wherein the lower frame includes an opening, through which the at least one sensor element is insertable or in which the sensor element is receivable.

9. The housing part of claim 1, wherein the at least one sensor element includes a surface wave component.

10. An electric sensor, comprising:
a first module including a sensor element; and
a second module, including the housing part of claim 1.

11. The electric sensor of claim 10, wherein the sensor element of the first module protrudes into the interior space of the housing part.

12. The electric sensor of claim 10, wherein the interior space present in the housing part is sealed with a lid.

13. A method of producing a housing part for an electric sensor including a sensor element, the housing part including an interior space for receiving the sensor element, the method comprising:
producing a contact layer made from electrically conducting material during production of the housing part by way of thick film technology, said contact layer being intended for realization of an electric feedthrough from the interior space to outside of the housing part.

14. The method of claim 13, further comprising:
producing a lower frame, a lower insulating layer, the contact layer, an upper insulating layer, and an upper frame one after the other during the manufacture of the housing part.

15. A method, comprising:
using the housing part of claim 1 to produce an electrical sensor;
producing a first module containing a sensor element, wherein the first module is produced independently from the production of the housing part constituting a second module; and
subsequently joining the first and the second modules.

16. The housing part of claim 1, wherein the electric sensor is a strain sensor.

17. The electric sensor of claim 10, wherein the electric sensor is a strain sensor.

18. The method of claim 13, wherein the electric sensor is a strain sensor.

19. The method of claim 15, wherein the electric sensor is a strain sensor.
